(19) United States
(12) Patent Application Publication
(10) Pub. No.: US 2026/0290756 A1
(43) Pub. Date: Sep. 24, 2026

(54) PLUG AND MEMBER FOR SEMICONDUCTOR MANUFACTURING APPARATUS

(71) Applicant: NGK Corporation, Nagoya-shi (JP)

(72) Inventors: Taro USAMI, Ginan-town (JP); Tatsuya KUNO, Nagoya-city (JP)

(21) Appl. No.: 19/670,084

(22) Filed: May 7, 2026

Related U.S. Application Data
(63) Continuation of application No. PCT/JP2025/025719, filed on Jul. 18, 2025.

(30) Foreign Application Priority Data
Nov. 22, 2024 (JP) 2024-203761
Apr. 22, 2025 (WO) PCT/JP2025/015620

(51) Int. Cl. H01J 37/32; H10P 72/72

(52) U.S. Cl. CPC H01J 37/32449; H01J 37/32715; H10P 72/722; H01J 2237/2007

(57) ABSTRACT

A plug of the present invention includes: an insulating and dense plug body; a gas flow path that penetrates from a lower portion of the plug body and opens at an upper surface thereof, and a part of which is exposed on the surface as a recessed portion when viewed from above; and a plug conductive film formed continuously along a wall surface of the recessed portion of the gas flow path and the upper surface of the plug body.

### CROSS-REFERENCE TO RELATED APPLICATION

This application is a continuation application of PCT/JP2025/025719, filed on Jul. 18, 2025, which claims the benefit of Japanese Patent Application No. 2024-203761 filed on Nov. 22, 2024 and International Application No. PCT/JP2025/015620 filed on Apr. 22, 2025, the entire contents of which are incorporated herein by reference.

### BACKGROUND OF THE INVENTION

### 1. Field of the Invention

The present invention relates to a plug and a member for semiconductor manufacturing apparatus.

### 2. Description of the Related Art

Conventionally, as a member for semiconductor manufacturing apparatus, a configuration is known in which a ceramic plate having a wafer placement surface is provided on a conductive base member. For example, PTL 1 discloses a configuration including a ceramic plate and a conductive cooling plate bonded to the ceramic plate, in which a porous plug is disposed in a plug insertion hole provided in the ceramic plate. This document also discloses, for example, extending the service life of the porous plug by covering a top surface of the porous plug with an electrically insulating protective lid having a large number of pores. Further, for example, PTL 2 discloses a configuration including a ceramic plate and a conductive cooling plate provided on a lower surface of the ceramic plate, in which a conductive plug that allows gas to flow to the wafer placement surface is disposed in a plug insertion hole penetrating the ceramic plate in the up-down direction. This document also discloses, for example, providing a large number of small protrusions on the wafer placement surface, providing a conductive coating that contacts a wafer on top surfaces of the small protrusions, and configuring the conductive plug to indirectly contact the wafer via the conductive coating.

### CITATION LIST

### Patent Literature

PTL 1: WO 2024/089762 A1
PTL 2: WO 2023/153021 A1

### SUMMARY OF THE INVENTION

Incidentally, some members for semiconductor manufacturing apparatus use an insulating, dense plug. However, when a wafer is plasma-processed using such a member for semiconductor manufacturing apparatus, discharge may occur in a gas flow path provided in the plug, particularly in a portion that is exposed on the surface when viewed from above, due to a potential difference in the up-down direction between the wafer and/or a focus ring and the conductive base member, which may lead to breakage of the member for semiconductor manufacturing apparatus.

The present invention has been made to solve such problems, and a primary object thereof is to suppress discharge in the gas flow path of a plug.

[1] A plug of the present invention includes: an insulating and dense plug body; a gas flow path that penetrates from a lower portion of the plug body and opens at an upper surface thereof, and a part of which is exposed on the surface as a recessed portion when viewed from above; and a plug conductive film formed continuously along a wall surface of the recessed portion of the gas flow path and the upper surface of the plug body.

In this plug, the plug conductive film is formed continuously along the wall surface of a portion of the gas flow path that is exposed on the surface as a recessed portion when viewed from above (hereinafter also referred to as a surface recessed portion) and the upper surface of the plug body. When no plug conductive film is formed, the larger the distance in the up-down direction between the wafer and/or the focus ring and the plug body, the larger the potential difference between them during plasma processing, and therefore discharge is likely to occur in the surface recessed portion that is recessed relative to surrounding portions. In contrast, in the plug of the present invention, the plug conductive film is formed continuously along the wall surface of the surface recessed portion and the upper surface of the plug body, so that the surface recessed portion and surrounding portions become equipotential. Accordingly, discharge in the surface recessed portion is suppressed.

In the present specification, the present invention may be described using up, down, left, right, front, back, and the like; however, these indicate merely relative positional relationships. Therefore, when the orientation of the member for semiconductor manufacturing apparatus is changed, up and down may become left and right, or left and right may become up and down, and such cases are also included in the technical scope of the present invention.

[2] In the plug (the plug described in [1] above), a length in the up-down direction from the upper surface of the plug body to a lower end of the recessed portion (hereinafter also referred to as a depth of the surface recessed portion) may be 18 or more and 10% or less of a length of the plug body in the up-down direction (hereinafter also referred to as a thickness of the plug). When the depth of the surface recessed portion is 1% or more of the thickness of the plug, a potential difference in the surface recessed portion becomes large and discharge tends to occur if no plug conductive film is provided; therefore, the significance of forming the plug conductive film to suppress discharge is high. Further, when the depth of the surface recessed portion is 10% or less of the thickness of the plug, bias in the potential distribution in the entirety of the gas flow path is relatively small, and occurrence of discharge in the gas flow path can be further suppressed.

[3] In the plug (the plug described in [1] or [2] above), the gas flow path may be formed in a spiral shape. This makes it possible to increase a creepage distance along the gas flow path to further suppress discharge and to smooth the flow of a thermally conductive gas.

[4] In the plug (the plug described in any one of [1] to [3] above), the plug conductive film may be a sputtered film. With sputtering, the plug conductive film can be formed relatively easily and uniformly not only on the upper surface of the plug body but also on the wall surface of the surface recessed portion.

[5] A member for semiconductor manufacturing apparatus of the present invention includes: a ceramic plate having, on its upper surface, a placement surface that is at least one of a wafer placement surface or a focus ring placement surface; and the plug (the plug described in any one of [1] to [4] above) disposed in a plug arrangement hole penetrating the ceramic plate in the up-down direction.

In this member for semiconductor manufacturing apparatus, since the above-described plug is provided, discharge in the gas flow path of the plug can be suppressed.

[6] In the member for semiconductor manufacturing apparatus (the member for semiconductor manufacturing apparatus described in [5] above), the plug may be disposed in the plug arrangement hole that opens to the focus ring placement surface. In general, the focus ring placement surface is formed one step lower than the wafer placement surface; therefore, the plug disposed in a portion of the ceramic plate corresponding to the focus ring has a shorter length in the up-down direction than the plug disposed in a portion corresponding to the wafer. Accordingly, a potential gradient in the gas flow path becomes large and discharge tends to occur, so that the significance of forming the plug conductive film to suppress discharge is high.

[7] The member for semiconductor manufacturing apparatus (the member for semiconductor manufacturing apparatus described in [5] or [6] above) may further comprise a conductive base member that is bonded to a lower surface of the ceramic plate and that is provided with a gas supply path communicating with the plug arrangement hole.

[8] The member for semiconductor manufacturing apparatus (the member for semiconductor manufacturing apparatus described in any one of [5] to [7] above) may further comprise, in a peripheral region around the plug arrangement hole in the placement surface, a peripheral-region conductive film formed with no gap from the plug conductive film or with a gap therefrom, wherein: the plug arrangement hole opens in a low-level surface that is lower than a support surface that supports a wafer or a focus ring in the placement surface; and the peripheral-region conductive film is formed from the support surface to the low-level surface. With this configuration, since the peripheral-region conductive film is formed from the support surface that contacts the wafer or the plug to the low-level surface where the plug arrangement hole opens, the wafer or the plug and the low-level surface become equipotential, the potential difference between the wafer or the plug and the surface recessed portion becomes small, and discharge in the surface recessed portion can be further suppressed. When the peripheral-region conductive film is formed with no gap from the plug conductive film, the wafer or the plug and the surface recessed portion become equipotential, so discharge between the wafer or the plug and the surface recessed portion can be further suppressed. On the other hand, when the peripheral-region conductive film is formed with a gap from the plug conductive film, the wafer or the plug and the surface recessed portion are not completely equipotential; however, a potential difference in portions of the gas flow path other than the surface recessed portion becomes smaller, thereby also suppressing discharge in portions of the gas flow path other than the surface recessed portion.

[9] In the member for semiconductor manufacturing apparatus (the member for semiconductor manufacturing apparatus described in [8] above), the peripheral region may be a region having a length, when viewed from above, of 7 mm or less from an outer peripheral edge of the plug arrangement hole.

[10] In the member for semiconductor manufacturing apparatus (the member for semiconductor manufacturing apparatus described in [8] or [9] above), a thickness of the peripheral-region conductive film may be Rz or less, where Rz is a maximum height roughness of the support surface. With this configuration, the peripheral-region conductive film falls within the range of surface irregularities of the support surface, so that the wafer or the focus ring can be firmly supported.

[11] The member for semiconductor manufacturing apparatus (the member for semiconductor manufacturing apparatus described in any one of [8] to [10] above) may further comprise an electrostatic electrode embedded in the ceramic plate, wherein: the electrostatic electrode has a through hole for allowing the plug to pass therethrough; and the peripheral-region conductive film is provided with a gap of 0.25 mm or more, when viewed from above, on an inner side of the through hole. When an electrostatic electrode is embedded in the ceramic plate, the effect of reducing the potential difference between the wafer or the focus ring and the surface recessed portion may be reduced due to, for example, the peripheral-region conductive film receiving influence of an electric field generated by the electrostatic electrode. However, by providing a gap of 0.25 mm or more, when viewed from above, between the peripheral-region conductive film and the electrostatic electrode, the influence of the electric field by the electrostatic electrode can be reduced.

[12] The member for semiconductor manufacturing apparatus (the member for semiconductor manufacturing apparatus described in any one of [5] to [7] above) may further comprise, in a peripheral region around the plug arrangement hole in the placement surface, a peripheral-region conductive film formed with a gap from the plug conductive film or with no gap therefrom, wherein: the plug arrangement hole opens in a low-level surface that is lower than a support surface that supports a wafer or a focus ring in the placement surface; and the peripheral-region conductive film is not formed on the support surface but is formed on the low-level surface. With this configuration, due to the presence of the peripheral-region conductive film, a potential difference between the wafer or the focus ring and the surface recessed portion can be reduced, and generation of particles and dust due to contact between the wafer or the focus ring and the peripheral-region conductive film can also be suppressed.

[13] In the member for semiconductor manufacturing apparatus (the member for semiconductor manufacturing apparatus described in [12] above), each film area of the peripheral-region conductive films may be 50 mm² or more. By setting each film area of the peripheral-region conductive films to 50 mm² or more, the potential difference between the wafer or the focus ring and the surface recessed portion can be further reduced.

[14] The member for semiconductor manufacturing apparatus (the member for semiconductor manufacturing apparatus described in [12] above) may further have an auxiliary conductive film formed continuously from the peripheral-region conductive film, wherein: the auxiliary conductive film is not formed on the support surface but is formed on the low-level surface; and a film area of each peripheral-region conductive film and a corresponding auxiliary conductive film is 50 mm² or more. By setting the film area of each peripheral-region conductive film and the corresponding auxiliary conductive film to 50 mm² or more, the potential difference between the wafer or the focus ring and the surface recessed portion can be further reduced.

### BRIEF DESCRIPTION OF DRAWINGS

FIG. 1 is a longitudinal cross-sectional view of a wafer placement table 10, which is an example of a member for semiconductor manufacturing apparatus of the present invention.

FIG. 2 is a plan view of a ceramic plate 20.

FIG. 3 is an explanatory view of a gas flow path 57.

FIGS. 4A and 4B are partially enlarged views of FIG. 1.

FIGS. 5A to 5D are manufacturing process diagrams of a plug 55.

FIGS. 6A and 6B are explanatory views of a plug 155.

FIGS. 7A and 7B are explanatory views of a plug 255.

FIG. 8 is a longitudinal cross-sectional view of a wafer placement table 310.

FIG. 9 is a plan view of a ceramic plate 320.

FIGS. 10A and 10B are partially enlarged views of FIG. 8.

FIG. 11 is a partially enlarged view corresponding to FIGS. 10A and 10B of another example of the wafer placement table 310.

FIG. 12 is a partially enlarged view corresponding to FIGS. 10A and 10B of still another example of the wafer placement table 310.

FIG. 13 is a longitudinal cross-sectional view of a wafer placement table 410.

FIG. 14 is a plan view of a ceramic plate 420.

FIGS. 15A and 15B are partially enlarged views of FIG. 13.

FIG. 16 is a longitudinal cross-sectional view of a wafer placement table 510.

FIG. 17 is a plan view of a ceramic plate 520.

FIG. 18 is a partially enlarged view of FIG. 16.

FIG. 19 is a plan view of another example of the ceramic plate 520.

FIG. 20 is an explanatory view of potential measurement locations in Experimental Examples 1 to 3.

FIGS. 21A and 21B are explanatory views in which a relationship between a length e and a potential difference ΔV_{FR-P1} is examined.

FIGS. 22A and 22B are explanatory views in which a relationship between a film area S and a potential difference ΔV_{FR-P1} is examined.

FIGS. 23A to 23C are explanatory views of a plug 655 of a reference embodiment.

### DETAILED DESCRIPTION OF THE INVENTION

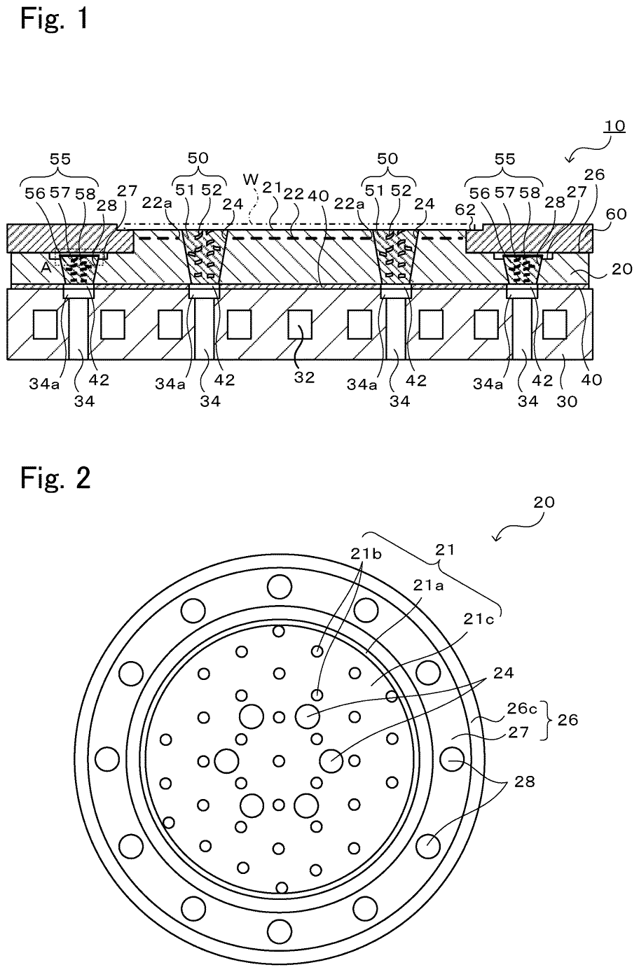

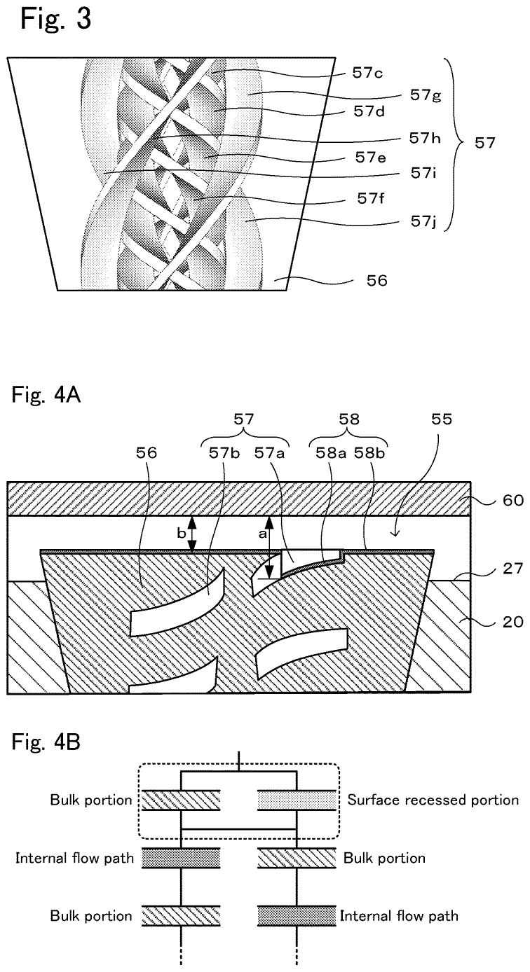

Preferred embodiments of the present invention will be described with reference to the drawings. FIG. 1 is a longitudinal cross-sectional view of a wafer placement table 10, which is an example of a member for semiconductor manufacturing apparatus of the present invention. FIG. 2 is a plan view of a ceramic plate 20. It should be noted that, in FIG. 2, components other than the ceramic plate 20 (e.g., a plug 50, a plug 55, and a plug conductive film 58) are not illustrated. FIG. 3 is an explanatory view of a gas flow path 57 (a perspective view of a plug body 56 as viewed from the front). FIGS. 4A and 4B are partially enlarged views of FIG. 1 (an enlarged view of a portion A surrounded by a broken line in FIG. 1). It should be noted that FIGS. 4A and 4B show, in addition to a partially enlarged view of FIG. 1 (FIG. 4A), an equivalent circuit (FIG. 4B) in which a bulk portion of the plug 55 and the gas flow path are regarded as capacitors.

The wafer placement table 10 includes a ceramic plate 20, a base plate 30, and a metal bonding layer 40. The ceramic plate 20 is provided with a plug arrangement hole 24 and a plug arrangement hole 28. A plug 50 is disposed in the plug arrangement hole 24, and a plug 55 is disposed in the plug arrangement hole 28.

The ceramic plate 20 is a ceramic disk (e.g., having a diameter of 300 mm) made of, for example, an alumina sintered body or an aluminum nitride sintered body. The thickness of the ceramic plate 20 is, for example, 1 mm or more and 5 mm or less. The ceramic plate 20 has, on its upper surface, a wafer placement surface 21 and a focus ring (FR) placement surface 26. The wafer placement surface 21 is a circular surface on which a wafer W is placed. As shown in FIG. 2, a seal band 21a is formed along an outer edge of the wafer placement surface 21, and a plurality of circular small protrusions 21b are formed over an entire surface thereof. The seal band 21a and the circular small protrusions 21b have the same height, and the height is, for example, several μm to several tens of μm. A portion of the wafer placement surface 21 where the seal band 21a and the circular small protrusions 21b are not provided is referred to as a reference surface 21c. The wafer W is supported on an upper surface of the seal band 21a and upper surfaces of the circular small protrusions 21b (wafer support surfaces). The FR placement surface 26 is an annular surface provided around the wafer placement surface 21, on which a focus ring 60 is placed. The height of the FR placement surface 26 is one step lower than the height of the wafer placement surface 21. As shown in FIG. 2, an annular recessed portion 27 extending around the FR placement surface 26 is formed in the FR placement surface 26. The depth of the recessed portion 27 is, for example, 5 μm or more and 15 μm or less. A portion of the FR placement surface 26 where the recessed portion 27 is not formed is referred to as an FR support surface 26c. The focus ring 60 is supported by the FR support surface 26c. The focus ring 60 is an annular member, and is made of, for example, Si. A circumferential groove 62 is provided on an upper portion of an inner side surface of the focus ring 60 so as not to contact the wafer W. The outer diameter of the focus ring 60 is larger than the outer diameter of the ceramic plate 20. Therefore, the focus ring 60 is placed on the FR placement surface 26 in a state protruding outward (overhanging) from the wafer placement table 10. The ceramic plate 20 includes a built-in electrode 22. The electrode 22 is a planar mesh electrode used as an electrostatic electrode and is configured to be applicable with a DC voltage. When a DC voltage is applied to the electrode 22, the wafer W is attracted and fixed to the wafer placement surface 21 (specifically, the upper surface of the seal band 21a and the upper surfaces of the circular small protrusions 21b) by an electrostatic attraction force, and when the application of the DC voltage is stopped, the attraction and fixing of the wafer W to the wafer placement surface 21 is released. The electrode 22 is provided with a through hole 22a for allowing the plug 50 to pass therethrough.

The plug arrangement hole 24 is a hole penetrating the ceramic plate 20 in the up-down direction, and is a through hole extending from the lower surface of the ceramic plate 20 to the wafer placement surface 21. The plug arrangement hole 24 faces a gas hole (gas supply path) 34 of the base plate 30. The plug arrangement hole 24 penetrates the electrode 22 in the up-down direction, but the electrode 22 is not exposed on an inner peripheral surface of the plug arrangement hole 24. The plug arrangement hole 24 is a tapered hole having a truncated-cone space tapering toward the bottom. As shown in FIG. 2, the plug arrangement hole 24 is provided at a plurality of locations (e.g., a plurality of locations provided at equal intervals along a circumferential direction) so as to open to the wafer placement surface 21 of the ceramic plate 20.

The plug arrangement hole 28 is a hole penetrating the ceramic plate 20 in the up-down direction, and is a through hole extending from the lower surface of the ceramic plate 20 to the FR placement surface 26. The plug arrangement hole 28 faces the gas hole 34 of the base plate 30. The plug arrangement hole 28 is a tapered hole having a truncated-cone space tapering toward the bottom. As shown in FIG. 2, the plug arrangement hole 28 is provided at a plurality of locations (e.g., a plurality of locations provided at equal intervals along the circumferential direction) so as to open to the FR placement surface 26 of the ceramic plate 20. Here, the plug arrangement hole 28 is provided in the recessed portion 27 of the FR placement surface 26.

The base plate 30 is an example of a conductive base member, and is a conductive disk having good thermal conductivity (a disk having the same diameter as the ceramic plate 20 or a larger diameter). Inside the base plate 30, a refrigerant flow path 32 through which a refrigerant (e.g., an electrically insulating liquid such as a fluorine-based inert liquid) circulates and gas holes 34 that supply gas to the plug 50 and the plug 55 are formed. The gas hole 34 is provided so as to penetrate the base plate 30 in the up-down direction, and has a large-diameter portion 34a on an upper side. The large-diameter portion 34a includes, in plan view, a lower opening portion of the plug arrangement hole 24. The refrigerant flow path 32 is formed, in plan view, over the entire surface of the base plate 30 from an inlet to an outlet in a one-stroke pattern. Examples of a material of the base plate 30 include metals and composite materials. Examples of the metal include Mo. Examples of the composite material include composite materials of metal and ceramic. Examples of the composite material of metal and ceramic include a metal matrix composite (MMC) and a ceramic matrix composite (CMC). Specific examples of such composite materials include materials containing Si, SiC, and Ti, and materials obtained by impregnating a porous SiC body with Al and/or Si. A material containing Si, SiC, and Ti is referred to as SisiCTi, a material obtained by impregnating a porous SiC body with Al is referred to as AlSiC, and a material obtained by impregnating a porous SiC body with Si is referred to as SiSiC. As a material of the base plate 30, it is preferable to select a material having a thermal expansion coefficient close to that of the material of the ceramic plate 20. The base plate 30 is also used as an RF electrode. Specifically, an upper electrode (not illustrated) is disposed above the wafer placement surface 21, and when high-frequency power is applied between parallel plate electrodes constituted by the upper electrode and the base plate 30, plasma is generated.

The metal bonding layer 40 bonds the lower surface of the ceramic plate 20 and the upper surface of the base plate 30. The metal bonding layer 40 is formed by, for example, TCB (Thermal Compression Bonding). TCB refers to a known method in which a metal bonding material is sandwiched between two members to be bonded, and the two members are pressure-bonded in a state of being heated to a temperature equal to or lower than a solidus temperature of the metal bonding material. The metal bonding layer 40 may be a layer formed of solder or a metal brazing material. The metal bonding layer 40 has a through hole 42. The through hole 42 is provided at a position facing the large-diameter portion 34a of the gas hole 34. The through hole 42 is provided coaxially with the large-diameter portion 34a, and the diameter of the through hole 42 matches the diameter of the large-diameter portion 34a. In the present specification, “coaxial” includes not only being completely coaxial but also being substantially coaxial (e.g., within a tolerance range) (the same applies hereinafter). In the present specification, “match” includes not only completely matching but also substantially matching (e.g., within a tolerance range) (the same applies hereinafter).

The plug 50 is disposed in the plug arrangement hole 24 that opens to the wafer placement surface 21. An upper surface of the plug 50 is arranged flush with the reference surface 21c. The plug 50 may be bonded to the plug arrangement hole 24 with an adhesive or the like, or may be fitted into the plug arrangement hole 24. The plug 50 is an electrically insulating member that allows gas to flow in the up-down direction. Here, the plug 50 is a ceramic member made of alumina, aluminum nitride, or the like, and is formed of, for example, the same material as the ceramic plate 20. The plug 50 has a truncated-cone shape tapering toward the bottom, and includes an insulating, dense plug body 51 and a gas flow path 52 that penetrates from a lower portion (here, a lower surface) of the plug body 51 and opens at an upper surface thereof. The dense state may be such that the porosity is 5% or less (preferably 3% or less, more preferably 1% or less). The gas flow path 52 is, for example, formed in a spiral shape similarly to a gas flow path 57 described later.

The plug 55 is disposed in the plug arrangement hole 28 that opens to the FR placement surface 26. An upper surface of the plug 55 is arranged at a position lower than an upper surface of the FR placement surface 26 (FR support surface 26c) and higher than a bottom surface of the recessed portion 27. The plug 55 may be bonded to the plug arrangement hole 28 with an adhesive or the like, or may be fitted into the plug arrangement hole 28. The plug 55 is an electrically insulating member that allows gas to flow in the up-down direction. Here, the plug 55 is a ceramic member made of alumina, aluminum nitride, or the like, and is formed of, for example, the same material as the ceramic plate 20. The plug 55 has a truncated-cone shape tapering toward the bottom, and includes an insulating, dense plug body 56 and a gas flow path 57 that penetrates from a lower portion (here, a lower surface) of the plug body 56 and opens at an upper surface thereof. Here, as the gas flow path 57, first to eighth gas flow paths 57c to 57j are provided. Each of the first to eighth gas flow paths 57c to 57j is a flow path that allows gas to flow, and is provided so as to extend from a lower opening provided on the lower surface of the plug body 56 to an upper opening provided on the upper surface thereof. The first to fourth gas flow paths 57c to 57f are formed by forming a flat band-shaped flow path having a rectangular cross section in a spiral shape so as to rotate clockwise from top to bottom. The first to fourth gas flow paths 57c to 57f are provided so as to be shifted by 90° each in the circumferential direction. The fifth to eighth gas flow paths 57g to 57j are formed by forming a flat band-shaped flow path having a rectangular cross section in a spiral shape so as to rotate counterclockwise from top to bottom. The fifth to eighth gas flow paths 57g to 57j are provided so as to be shifted by 90° each in the circumferential direction. The fifth to eighth gas flow paths 57g to 57j are provided on an outer peripheral side relative to the first to fourth gas flow paths 57c to 57f. Each of the gas flow paths 57 (each of the first to eighth gas flow paths 57c to 57j) is formed such that a part thereof is exposed on the surface as a recessed portion when viewed from above and such that the lower opening cannot be seen through. Hereinafter, a portion of the gas flow path 57 exposed on the surface as a recessed portion when viewed from above is also referred to as a surface recessed portion 57a, and the other portion is also referred to as an internal flow path 57b.

The plug 55 includes a plug conductive film 58 formed continuously along a wall surface of the surface recessed portion 57a of the gas flow path 57 and an upper surface of the plug body 56. A plug conductive film 58a formed on the wall surface of the surface recessed portion 57a is continuous with a plug conductive film 58b formed on the upper surface of the plug body 56. Accordingly, the wall surface of the surface recessed portion 57a and the upper surface of the plug body 56 become equipotential, and, as compared with a case where the plug conductive film 58 is omitted, a potential difference in the surface recessed portion 57a is alleviated and discharge in the surface recessed portion 57a is suppressed. The plug conductive film 58 can be formed by, for example, a physical vapor deposition (PVD) method such as sputtering, or a plating method such as electroless plating. The plug conductive film 58 is preferably a sputtered film. Examples of a material of the plug conductive film 58 include metal materials, and metals excellent in corrosion resistance such as Au, Ag, Al, Ti, SUS316L, or Hastelloy (Ni—Fe—Mo-based alloy; Hastelloy is a registered trademark) are preferable. The thickness of the plug conductive film 58 may be, for example, 0.5 μm or more and 5 μm or less. The plug conductive film 58 is preferably formed over the entire surface with no gap when the plug 55 is viewed from above.

Next, an example of use of the wafer placement table 10 configured as described above will be described. First, with the wafer placement table 10 installed in a chamber (not illustrated), the focus ring 60 is placed on the FR placement surface 26, and the wafer W is placed on the wafer placement surface 21. Then, the inside of the chamber is depressurized by a vacuum pump and adjusted to a predetermined degree of vacuum, and a DC voltage is applied to the electrode 22 of the ceramic plate 20 to generate an electrostatic attraction force, thereby causing the wafer W to be attracted and fixed to the wafer placement surface 21 (specifically, the upper surface of the seal band 21a and the upper surfaces of the circular small protrusions 21b). Next, the inside of the chamber is set to a reaction gas atmosphere at a predetermined pressure (e.g., several tens to several hundreds Pa), and in this state, a high-frequency voltage is applied between an upper electrode (not illustrated) provided in a ceiling portion in the chamber and the base plate 30 of the wafer placement table 10 to generate plasma. The surface of the wafer W is processed by the generated plasma. A refrigerant is circulated through the refrigerant flow path 32 of the base plate 30. A backside gas is introduced into the gas hole 34 from a gas cylinder (not illustrated). As the backside gas, a thermally conductive gas (e.g., helium) is used. The backside gas is supplied and sealed into a space between a back surface of the wafer W and the reference surface 21c of the wafer placement surface 21 through the gas hole 34, the through hole 42, and the plug 50. Further, the backside gas is supplied and sealed into a space between a back surface of the focus ring 60 and the recessed portion 27 of the FR placement surface 26 through the gas hole 34, the through hole 42, and the plug 55. Due to the presence of the backside gas, heat conduction between the wafer W and the ceramic plate 20 and heat conduction between the focus ring 60 and the ceramic plate 20 are efficiently performed. Further, due to the presence of the electrically insulating plugs 50 and 55 disposed in the plug arrangement holes 24 and 28, a creepage distance between the wafer W and the base plate 30 and a creepage distance between the focus ring 60 and the base plate 30 become longer, for example, thereby suppressing occurrence of discharge in the plug arrangement hole 24 and the plug arrangement hole 28.

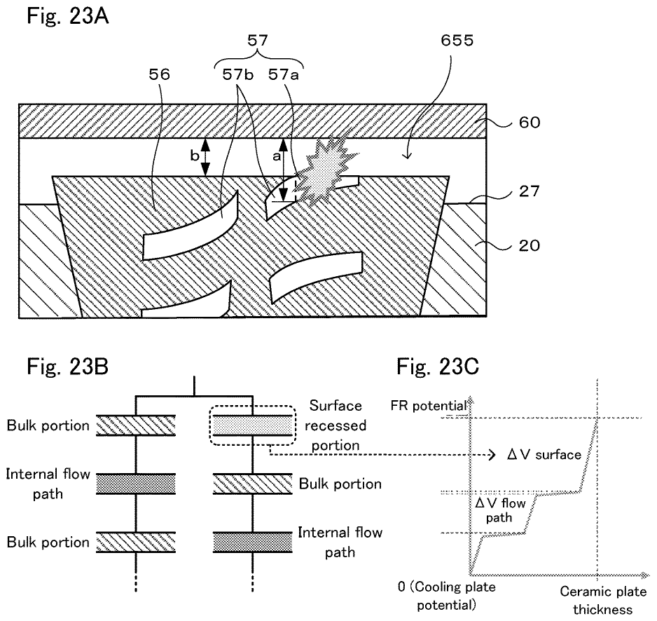

Incidentally, when the plug conductive film 58 of the plug 55 is omitted, abnormal discharge may occur in the gas flow path 57, particularly in the surface recessed portion 57a. This point will be described with reference to FIGS. 23A to 23C. FIGS. 23A to 23C are explanatory views of a plug 655 of a reference embodiment. FIG. 23A is a partially enlarged view corresponding to FIG. 4A when the plug 655 is used instead of the plug 55. FIG. 23B is an equivalent circuit in which a bulk portion of the plug 655 (a portion of the plug body 56 sandwiched by the gas flow path 57, and a portion disposed immediately above or below the gas flow path 57) and the gas flow path are regarded as capacitors. FIG. 23C is an explanatory view showing a potential distribution in a circuit in which the surface recessed portion is connected in series in the equivalent circuit of FIG. 23B. For example, considering the cross section shown in FIG. 23A, the equivalent circuit of the plug 655 can be assumed to have: a right-side series portion in which the surface recessed portion 57a, a bulk portion therebelow, an internal flow path 57b therebelow, a bulk portion therebelow, an internal flow path 57b therebelow, . . . (hereinafter, repetition of the bulk portion and the internal flow path 57b) . . . are connected in series as respective capacitors; and a left-side series portion in which a bulk portion, an internal flow path 57b therebelow, a bulk portion therebelow, an internal flow path 57b therebelow, a bulk portion therebelow, . . . (hereinafter, repetition of the internal flow path 57b and the bulk portion) . . . are connected in series as respective capacitors. During plasma processing, a potential difference in the up-down direction occurs between the focus ring 60 and the base plate 30; however, since the dielectric constant of the thermally conductive gas flowing in the gas flow path 57 is lower than the dielectric constant of the bulk portion, a potential gradient in the gas flow path 57 becomes large in each series portion. In the gas flow path 57, an up-down directional length a of the surface recessed portion 57a is longer than an up-down directional length b of the internal flow path 57b by an amount corresponding to a gap between the focus ring 60 and the plug 655; therefore, an up-down directional potential difference becomes particularly large in the surface recessed portion 57a (see FIG. 23C). Accordingly, when the plug 655 of the reference embodiment is used, discharge tends to occur in the surface recessed portion 57a. On the other hand, in the plug 55 of the embodiment, the plug conductive film 58 is formed continuously along the wall surface of the surface recessed portion 57a and the upper surface of the plug body 56. Therefore, the surface recessed portion 57a and a surrounding portion thereof (the uppermost bulk portion in the left-side series portion) can be regarded as a parallel circuit, and a potential difference between the surface recessed portion 57a and the surrounding portion can be reduced. As a result, ΔVsurface in FIG. 23C can be reduced, and discharge in the surface recessed portion 57a can be suppressed.

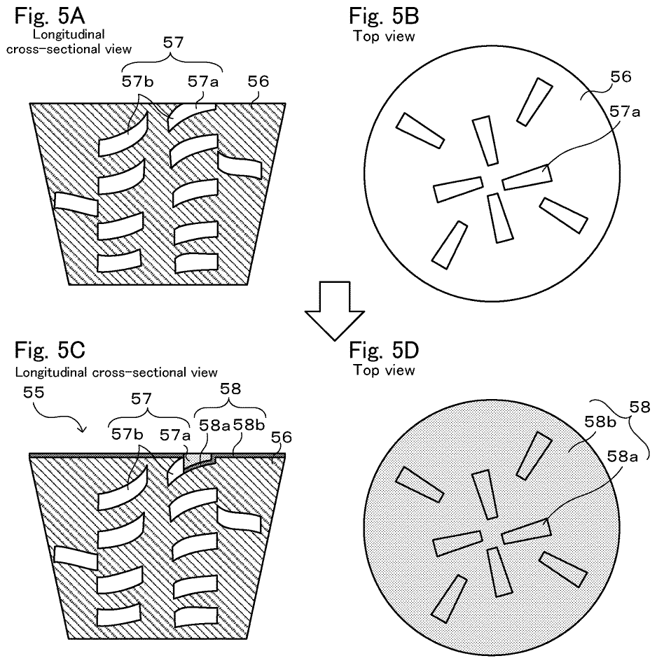

Next, a manufacturing example of the plug 55 will be described. FIGS. 5A to 5D are manufacturing process diagrams of the plug 55. First, a plug body 56 in which the gas flow path 57 is formed is prepared (FIGS. 5A and 5B). The plug body 56 is manufactured, for example, by firing a molded body produced by mold-cast molding. The molded body is to become the plug 55 after firing, and dimensions of the molded body are determined based on dimensions of the plug 55 in consideration of shrinkage during firing. The molded body has, inside a molded-body main portion, a hollow portion that becomes the gas flow path 57 after firing. In mold-cast molding, a ceramic slurry containing ceramic powder, a solvent, a dispersant, and a gelling agent is injected into a molding space of a mold, and the ceramic slurry is gelled by causing the gelling agent to chemically react, thereby producing a molded body in the mold. As the mold, a mold having a bottomed cylindrical mold main body and a core corresponding to a hollow portion of the molded body (a portion that ultimately becomes the spiral gas flow path 57) and having a molding space having the same shape as the molded body can be used. Such a mold can be produced using, for example, a 3D printer. As a material of the mold, a material insoluble in components contained in the ceramic slurry described later (e.g., wax such as paraffin wax) can be used. Then, the mold is removed by melting removal or the like from an integrated body in which the mold and the molded body are integrated, thereby obtaining the molded body. Subsequently, the molded body is degreased and then fired to produce the plug body 56. Such a plug body 56 may be produced, for example, in accordance with a plug molding method disclosed in JP 2024-88883 A.

Subsequently, the plug conductive film 58 is formed on the plug body 56 in which the gas flow path 57 is formed (FIGS. 5C and 5D). The plug conductive film 58 is formed, for example, by sputtering a conductive material from an upper-surface side of the plug body 56. Examples of the conductive material include metal materials, and metals excellent in corrosion resistance such as Au, Ag, Al, Ti, SUS316L, or Hastelloy (Ni—Fe—Mo-based alloy; Hastelloy is a registered trademark) are preferable. In forming the plug conductive film 58, conditions are adjusted so that not only the plug conductive film 58b is formed on the upper surface of the plug body 56, but also the plug conductive film 58a is formed on the wall surface of the surface recessed portion 57a that is exposed on the upper surface of the plug body 56 in the gas flow path 57. Thus, the plug 55 having the plug conductive film 58 is obtained.

As described above in detail, in the plug 55, the plug conductive film 58 (the plug conductive film 58a and the plug conductive film 58b) is formed continuously on the wall surface of the surface recessed portion 57a that is exposed on the surface when the gas flow path 57 is viewed from above, and on the upper surface of the plug body 56. Accordingly, discharge in the surface recessed portion 57a is suppressed. Further, since the plug 55 has the plug conductive film 58, breakage of a thinned ceramic portion around the surface recessed portion 57a of the plug body 56 can also be suppressed.

Further, in the plug 55, it is preferable that a length in the up-down direction from the upper surface of the plug body 56 to the lower end of the surface recessed portion 57a (a value obtained by subtracting the length b from the length a in FIGS. 4A and 4B) is 1% or more and 10% or less of a length of the plug body 56 in the up-down direction. When the depth of the surface recessed portion is 1% or more of the thickness of the plug 55, a potential difference in the surface recessed portion 57a becomes large and discharge tends to occur if the plug conductive film 58 is not provided; therefore, the significance of forming the plug conductive film 58 to suppress discharge is high. Further, when the depth of the surface recessed portion is 10% or less of the thickness of the plug 55, bias in the potential distribution in the entirety of the gas flow path 57 is relatively small, and occurrence of discharge in the gas flow path can be further suppressed.

Further, in the plug 55, since the gas flow path 57 is formed in a spiral shape, a creepage distance along the gas flow path 57 can be increased to further suppress discharge, and flow of a thermally conductive gas can be smoothed.

Further, in the plug 55, the plug conductive film 58 is preferably a sputtered film. With this configuration, the plug conductive film 58 can be formed relatively easily and uniformly not only on the upper surface of the plug body 56 but also on the wall surface of the surface recessed portion 57a. Further, it is possible to suppress the plug conductive film 58 from penetrating deeply into the internal flow path 57b. Further, during production of the plug 55, the ceramic around the surface recessed portion 57a may be chipped (also referred to as chipping); however, since a conductor can be provided on the chipped portion, the influence of chipping can be ignored.

Further, since the wafer placement table 10 includes the above-described plug 55, discharge in the gas flow path 57 of the plug 55 can be suppressed.

Further, in the wafer placement table 10, the plug 55 is disposed in the plug arrangement hole 28 that opens to the FR placement surface 26. Since the FR placement surface 26 is formed one step lower than the wafer placement surface 21, the plug 55 disposed in a portion of the ceramic plate 20 corresponding to the focus ring 60 has a shorter length in the up-down direction than the plug 50 disposed in a portion corresponding to the wafer W. Accordingly, as compared with the plug 50, a potential gradient in the gas flow path becomes larger and discharge tends to occur; therefore, the significance of forming the plug conductive film 58 to suppress discharge is high.

It should be noted that the present invention is not limited in any way to the above-described embodiment, and it goes without saying that the present invention can be implemented in various modes as long as they belong to the technical scope of the present invention.

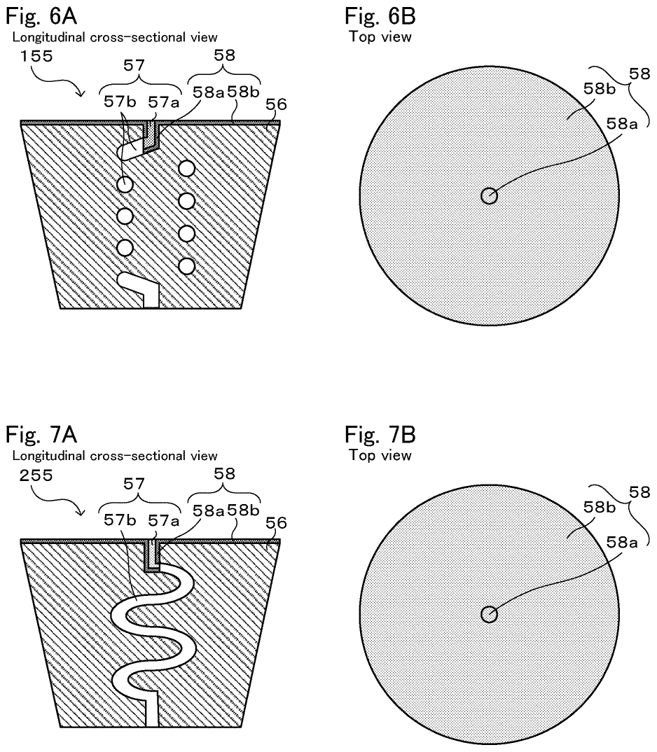

For example, in the above-described embodiment, the plug 55 has the first to eighth gas flow paths 57c to 57j as the gas flow path 57; however, the gas flow path 57 may be one path or may be two or more paths. Further, while each of the first to eighth gas flow paths 57c to 57j is a flat band-shaped flow path having a rectangular cross section, the cross-sectional shape is not particularly limited, and may be, for example, a flow path having a circular cross section as in a plug 155 shown in FIGS. 6A and 6B. Further, while each of the first to eighth gas flow paths 57c to 57j is spiral, the present invention is not limited thereto, and the gas flow path 57 may be configured to penetrate in the up-down direction while bending in the plug body 56, as in a plug 255 shown in FIGS. 7A and 7B. In FIGS. 6A and 6B and FIGS. 7A and 7B, the same reference signs are assigned to the same configurations as those of the above-described embodiment, and detailed description thereof is omitted.

In the above-described embodiment, the plug 50 and the plug 55 each have a truncated-cone shape tapering toward the bottom; however, the present invention is not limited thereto, and may have, for example, a cylindrical shape or a truncated-cone shape tapering toward the upper side.

In the above-described embodiment, the upper surface of the plug 55 is arranged at a position higher than the bottom surface of the recessed portion 27; however, it may be arranged at the same height as the bottom surface of the recessed portion 27 or at a lower position.

In the above-described embodiment, the annular recessed portion 27 is formed in the FR placement surface 26; however, the recessed portion 27 does not have to be annular, and may be, for example, a circular recessed portion that is arranged coaxially with the plug arrangement hole 28 and has a larger diameter than the plug arrangement hole 28. Further, the recessed portion 27 may not be formed in the FR placement surface 26. When the recessed portion 27 is not formed in the FR placement surface 26, the plug 55 is arranged so that the upper surface of the plug 55 does not become higher than the FR placement surface 26.

In the above-described embodiment, the plug 50 does not have a plug conductive film; however, the plug 50 may also have a plug conductive film similar to the plug conductive film 58 of the plug 55. When the plug 50 has the plug conductive film, the plug conductive film 58 of the plug 55 may be omitted.

In the above-described embodiment, a wafer placement table 10 having the wafer placement surface 21 and the FR placement surface 26 has been described as an example of the member for semiconductor manufacturing apparatus of the present invention; however, the wafer placement table 10 may not have the FR placement surface 26. In that case, the plug 50 has a plug conductive film similar to the plug conductive film 58 of the plug 55. Further, the member for semiconductor manufacturing apparatus of the present invention may be a focus ring placement table having the FR placement surface 26 and not having the wafer placement surface.

In the above-described embodiment, the seal band 21a and the circular small protrusions 21b are formed on the wafer placement surface 21; however, the seal band 21a and the circular small protrusions 21b may not be formed. The wafer placement surface 21 may be, for example, a flat surface (only the reference surface 21c). In that case, the wafer W is supported on the reference surface 21c.

In the above-described embodiment, the upper surface of the plug 50 is arranged flush with the reference surface 21c; however, the present invention is not particularly limited thereto as long as the upper surface of the plug 50 does not exceed the upper surfaces of the circular small protrusions 21b, and may be arranged, for example, at a position lower than the reference surface 21c.

In the above-described embodiment, the electrode 22 is arranged at a position corresponding to the wafer placement surface 21; however, instead of this or in addition thereto, the electrode 22 may be arranged at a position corresponding to the FR placement surface 26.

In the above-described embodiment, the electrostatic electrode has been exemplified as the electrode 22 embedded in the ceramic plate 20; however, the present invention is not particularly limited thereto. For example, instead of the electrode 22 or in addition thereto, the ceramic plate 20 may include a built-in heater electrode (resistance heating element) or may include a built-in RF electrode.

In the above-described embodiment, the ceramic plate 20 and the base plate 30 are bonded by the metal bonding layer 40; however, a resin adhesive layer may be used instead of the metal bonding layer 40.

In the above-described embodiment, a plurality of gas holes 34 constituting the gas supply path are independently provided in the base plate 30; however, the present invention is not particularly limited thereto. For example, the gas hole 34 may have one or a plurality of introduction portions through which gas is introduced from a back surface of the base plate 30, and may branch from the introduction portion(s) and open at positions facing the plug arrangement hole 24 and the plug arrangement hole 28. With this configuration, the number of external gas pipes connected to the lower surface of the base plate 30 can be smaller than the number of the plugs 50 and 55.

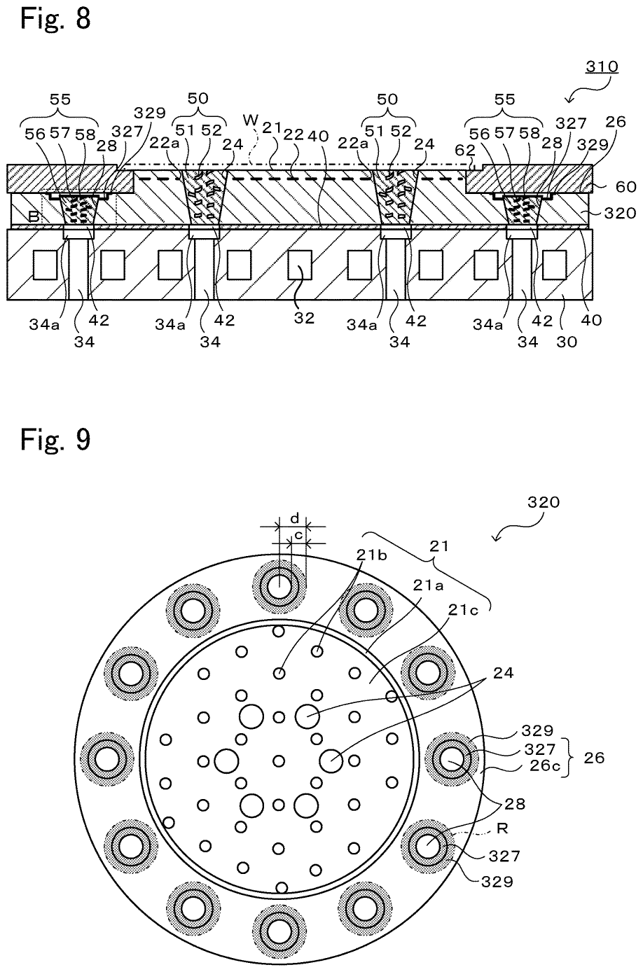

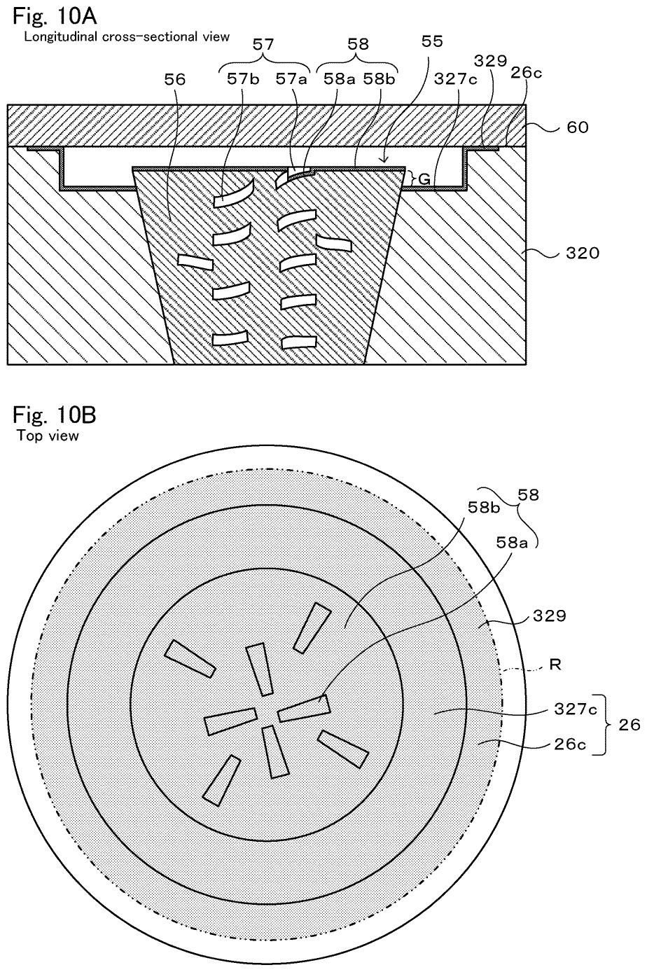

In the above-described embodiment and the other examples, the wafer placement table 10 is configured such that the plug 55 includes the plug conductive film 58; however, as in a wafer placement table 310 shown in FIGS. 8 to 10, a peripheral-region conductive film 329 may further be formed in a peripheral region R (a region surrounded by a two-dot chain line in FIG. 9) around the plug arrangement hole 28 in the FR placement surface 26. FIG. 8 is a longitudinal cross-sectional view of a wafer placement table 310, which is an example of the member for semiconductor manufacturing apparatus of the present invention. FIG. 9 is a plan view of a ceramic plate 320. It should be noted that, in FIG. 9, components other than the ceramic plate 320 and the peripheral-region conductive film 329 (e.g., the plug 50, the plug 55, and the plug conductive film 58) are not illustrated. FIGS. 10A and 10B are partially enlarged views of FIG. 8 (an enlarged view of a portion B surrounded by a broken line in FIG. 8). It should be noted that FIGS. 10A and 10B show, in addition to a partially enlarged view of FIG. 8 (FIG. 10A), a top view obtained by removing the focus ring 60 from FIG. 10A and viewing from above. The wafer placement table 310 is configured similarly to the wafer placement table 10 except that, instead of the annular recessed portion 27 extending around the FR placement surface 26, a circular recessed portion 327 arranged coaxially with the plug arrangement hole 28 is provided, and the ceramic plate 320 in which the peripheral-region conductive film 329 is formed on the FR placement surface 26 is included. The depth of the recessed portion 327 is, for example, 5 μm or more and 15 μm or less. In FIGS. 8 to 10, the same reference signs are assigned to the same configurations as those of the above-described embodiment. The peripheral-region conductive film 329 is formed with a gap G from the plug conductive film 58 in the up-down direction. A length of the gap G (the shortest distance between the plug conductive film 58 and the peripheral-region conductive film 329; the same applies hereinafter) is preferably shorter from a viewpoint of conduction to a surface portion of the plug, and is preferably 2 μm or less, more preferably 1 μm or less. The length of the gap G is preferably longer from a viewpoint of reducing a potential difference in the internal flow path 57b, and is preferably 0.5 μm or more, more preferably 1 μm or more. As shown in FIGS. 10A and 10B, the peripheral-region conductive film 329 is formed continuously from the FR support surface 26c to a low-level surface 327c (the bottom surface of the recessed portion 327) where the plug arrangement hole 28 opens. When the focus ring 60 contacts the peripheral-region conductive film 329, the focus ring 60 and the low-level surface 327c become equipotential. The peripheral-region conductive film 329 is preferably formed over the entire circumference of the plug arrangement hole 28. The peripheral region R is preferably a region that does not overlap, in plan view, an embedded electrode (an electrode 423 described later) embedded in the ceramic plate 320, and is preferably a region having a smaller diameter than a through hole (a through hole 423a described later) provided in the embedded electrode to allow the plug to pass therethrough. With this configuration, the peripheral-region conductive film 329 does not interfere with the embedded electrode, and thus, for example, when the embedded electrode is an electrostatic electrode, a decrease in attraction force and the like can be suppressed. The peripheral region R may be a region in which a length c (see FIG. 9) from an outer peripheral edge of the plug arrangement hole 28 in plan view is 7 mm or less, may be 5 mm or less, or may be 2 mm or less. Further, the peripheral region R may be a region in which a length d (see FIG. 9) from a central axis of the plug arrangement hole is 10 mm or less, or may be 8 mm or less. The thickness of the peripheral-region conductive film 329 is preferably Rz or less, where Rz is a maximum height roughness of the FR support surface 26c. With this configuration, since the peripheral-region conductive film 329 falls within the range of irregularities of the FR support surface 26c, the focus ring can be firmly supported. Specifically, the thickness of the peripheral-region conductive film 329 is preferably, for example, 3 μm or less, more preferably 1 μm or less. The thickness of the peripheral-region conductive film 329 may be, for example, 0.1 μm or more, or may be 0.5 μm or more. The peripheral-region conductive film 329 can be formed by, for example, a PVD method such as sputtering, or a plating method such as electroless plating. The peripheral-region conductive film 329 is preferably a sputtered film. Examples of a material of the peripheral-region conductive film 329 include metal materials, and metals excellent in corrosion resistance such as Au, Ag, Al, Ti, SUS316L, or Hastelloy (Ni—Fe—Mo-based alloy; Hastelloy is a registered trademark) are preferable. The peripheral-region conductive film 329 may be formed together with the plug conductive film 58 after the plug 55 is disposed in the plug arrangement hole 28, or may be formed before the plug 55 is disposed in the plug arrangement hole 28.

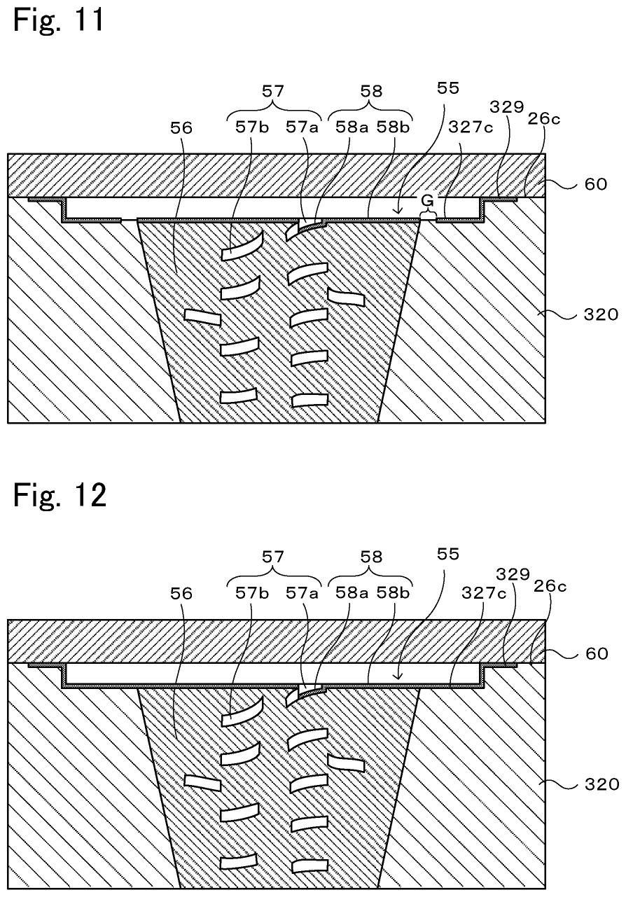

In the above-described wafer placement table 310, the peripheral-region conductive film 329 is formed with the gap G from the plug conductive film 58 in the up-down direction; however, as in another example shown in FIG. 11, it may be formed with the gap G from the plug conductive film 58 in an in-plane direction. In this case as well, a preferable range of the gap G is the same as the above-described range. In this case, a conductive film may be prevented from being formed in a portion corresponding to the gap G by masking or the like, or a conductive film formed in the portion corresponding to the gap G may be removed by post-processing. In FIG. 11, the same reference signs are assigned to the same configurations as those of the wafer placement table 310.

In the above-described wafer placement table 310, the peripheral-region conductive film 329 is formed with the gap G from the plug conductive film 58 in the up-down direction; however, as in another example shown in FIG. 12, it may be formed with no gap G from the plug conductive film 58. In this case, since the focus ring 60 and the surface recessed portion 57a become equipotential, discharge between the focus ring 60 and the surface recessed portion 57a can be further suppressed as compared with the wafer placement table 310. In FIG. 12, the same reference signs are assigned to the same configurations as those of the wafer placement table 310.

In the above-described wafer placement table 310 and the other examples, the peripheral-region conductive film is not formed on the wafer placement surface 21; however, when the plug 50 has the plug conductive film, a peripheral-region conductive film similar to the peripheral-region conductive film 329 may also be formed in a peripheral region around the plug arrangement hole 24 in the wafer placement surface 21.

In the above-described wafer placement table 310 and the other examples, the FR placement surface 26 of the ceramic plate 320 may have the annular recessed portion 27 instead of the circular recessed portion 327.

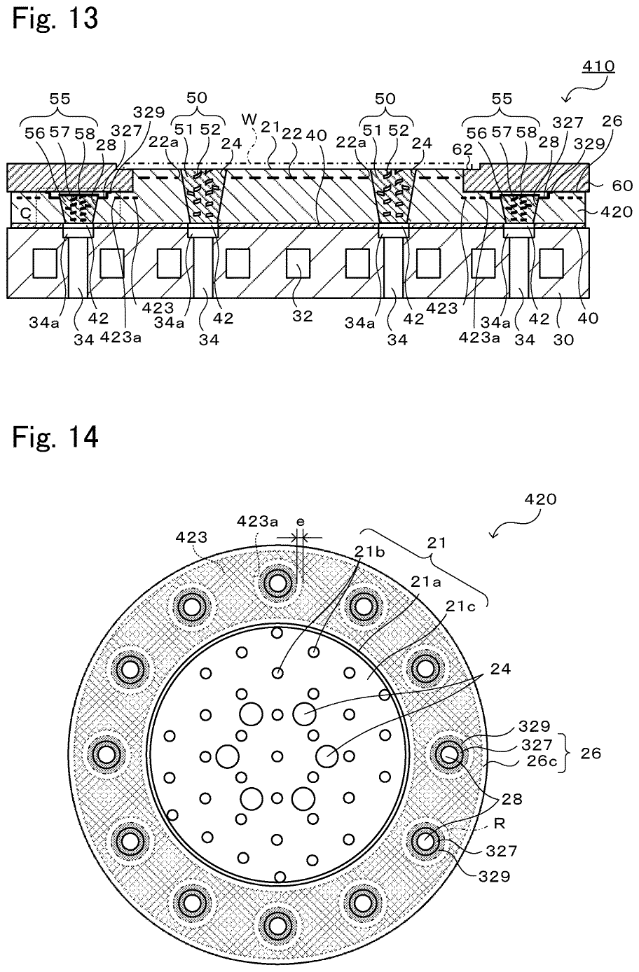

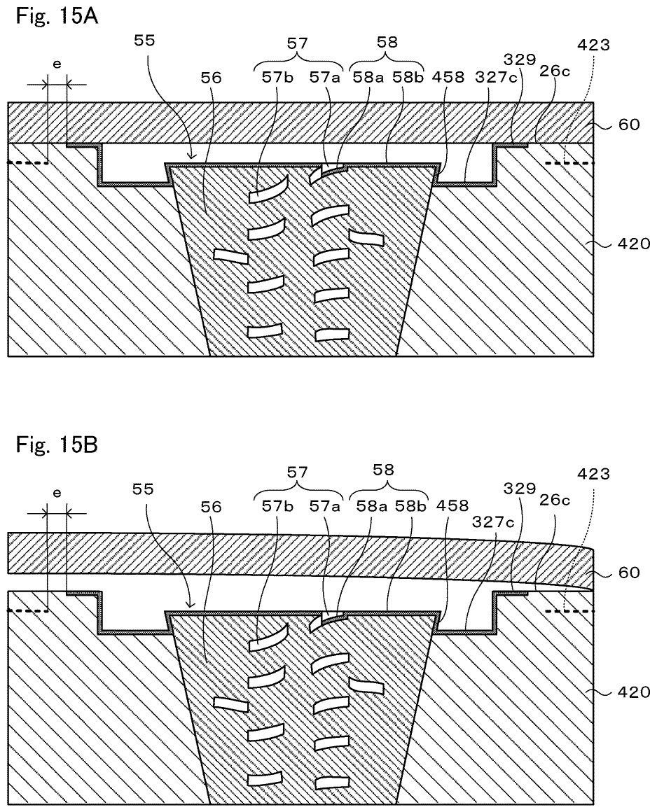

In the above-described wafer placement table 310 and the other examples, the ceramic plate 320 is configured to include the built-in electrode 22 arranged at a position corresponding to the wafer placement surface 21. Alternatively, instead of the built-in electrode 22 or in addition thereto, a built-in electrostatic electrode 423 arranged at a position corresponding to the FR placement surface 26 may be provided. FIG. 13 is a longitudinal cross-sectional view of a wafer placement table 410, which is an example of the member for semiconductor manufacturing apparatus of the present invention. FIG. 14 is a plan view of a ceramic plate 420. In FIG. 14, the built-in electrostatic electrode 423 is shown by a broken line and hatching. It should be noted that, in FIG. 14, components other than the ceramic plate 420 and the peripheral-region conductive film 329 (e.g., the plug 50, the plug 55, and the plug conductive film 58) are not illustrated. FIGS. 15A and 15B are partially enlarged views of FIG. 13 (an enlarged view of a portion C surrounded by a broken line in FIG. 13). FIGS. 15A and 15B show not only ideal cases where the peripheral-region conductive film 329 contacts the focus ring 60 (FIG. 15A) but also a case where the peripheral-region conductive film 329 does not contact the focus ring 60 due to warpage of the focus ring 60 or the like (FIG. 15B). The wafer placement table 410 is configured similarly to the wafer placement table 310 except that the wafer placement table 410 includes the ceramic plate 420 having the built-in electrostatic electrode 423 instead of the ceramic plate 320, and that the peripheral-region conductive film 329 and the plug conductive film 58 are connected by a connecting conductive film 458 and are formed with no gap therebetween. In FIGS. 13 to 15, the same reference signs are assigned to the same configurations as those of the above-described embodiments. The connecting conductive film 458 is formed at an upper end portion of an outer peripheral surface of the plug body 56 and electrically connects the plug conductive film 58 and the peripheral-region conductive film 329. As for a formation method, thickness, material, and the like of the connecting conductive film 458, those described for the plug conductive film 58 and the peripheral-region conductive film 329 can be appropriately adopted. The connecting conductive film 458 may be omitted. Further, in the above-described embodiments and the like, the connecting conductive film 458 may be appropriately adopted. The ceramic plate 420 is configured similarly to the ceramic plate 320 except that the ceramic plate 420 includes the electrostatic electrode 423 arranged at a position corresponding to the FR placement surface 26. The electrostatic electrode 423 is, for example, a planar mesh electrode and is configured to be applicable with a DC voltage. This DC voltage may be a voltage such that a potential difference ΔVc between the electrostatic electrode 423 and the focus ring 60 becomes larger than a potential difference ΔVb between the base plate and the focus ring 60 (e.g., ΔVc−ΔVb is 1000 V or more and 3000 V or less). When a DC voltage is applied to the electrostatic electrode 423, the focus ring 60 is attracted and fixed to the FR placement surface 26 (specifically, the FR support surface 26c) by an electrostatic attraction force, and when the application of the DC voltage is stopped, the attraction and fixing of the focus ring 60 to the FR placement surface 26 is released. The electrostatic electrode 423 may be embedded at a depth such that a distance from the FR support surface 26c is, for example, 200 μm or more and 500 μm or less. The electrostatic electrode 423 is provided with a through hole 423a for allowing the plug 55 to pass therethrough. The plug arrangement hole 28 penetrates the electrostatic electrode 423 in the up-down direction, but the electrostatic electrode 423 is not exposed on an inner peripheral surface of the plug arrangement hole 28. In the wafer placement table 410, in an ideal case where the peripheral-region conductive film 329 contacts the focus ring 60 (FIG. 15A), the peripheral-region conductive film 329 and the plug conductive film 58 become equipotential with the focus ring 60, so that a potential difference between the focus ring 60 and the low-level surface 327c, the surface recessed portion 57a, and the like can be reduced to substantially zero. On the other hand, when the peripheral-region conductive film 329 does not contact the focus ring 60 (FIG. 15B), the peripheral-region conductive film 329 and the plug conductive film 58 do not become equipotential with the focus ring 60, and depending on a positional relationship with the electrostatic electrode 423, a potential difference from the focus ring 60 may become relatively large due to an influence of an electric field of the electrostatic electrode 423. From a viewpoint of reducing such influence of the electric field of the electrostatic electrode 423, it is preferable that the peripheral-region conductive film 329 is provided with a gap of 0.25 mm or more, when viewed from above, on an inner side of the through hole 423a penetrating the electrostatic electrode 423. That is, it is preferable that a length e, which is a length in plan view between the peripheral-region conductive film 329 and the electrostatic electrode 423, is 0.25 mm or more. The length e is more preferably, for example, 0.3 mm or more, further preferably 0.5 mm or more. The length e may be, for example, 1 mm or less, may be 0.8 mm or less, or may be 0.75 mm or less.

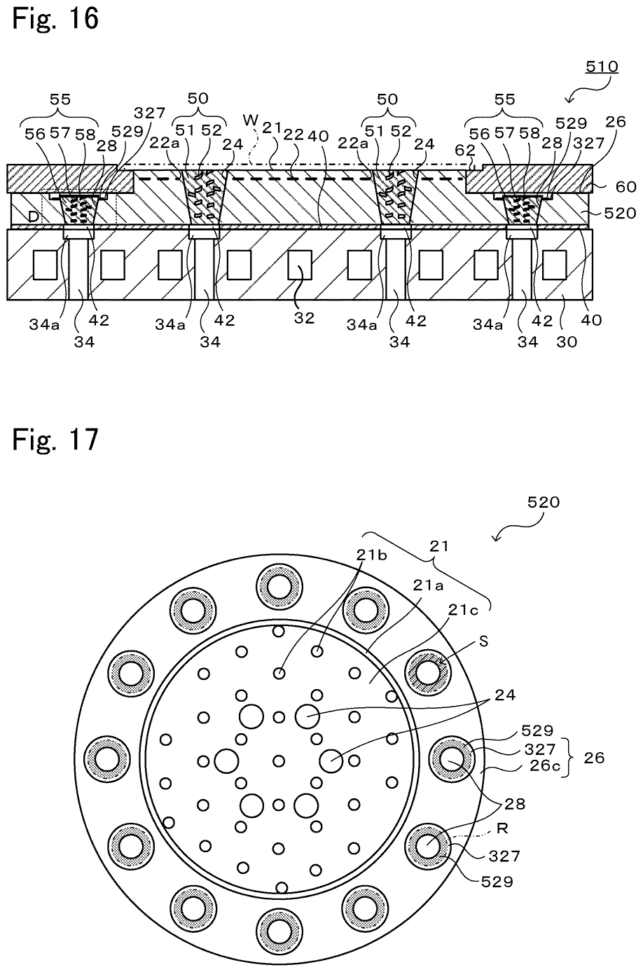

In the above-described wafer placement table 310 and wafer placement table 410, the peripheral-region conductive film 329 is formed continuously from the FR support surface 26c to the low-level surface 327c (the bottom surface of the recessed portion 327) where the plug arrangement hole 28 opens; however, the peripheral-region conductive film 329 does not have to be formed on the FR support surface 26c. FIG. 16 is a longitudinal cross-sectional view of a wafer placement table 510, which is an example of the member for semiconductor manufacturing apparatus of the present invention. FIG. 17 is a plan view of a ceramic plate 520. It should be noted that, in FIG. 17, components other than the ceramic plate 520 and a peripheral-region conductive film 529 (e.g., the plug 50, the plug 55, and the plug conductive film 58) are not illustrated. FIG. 18 is a partially enlarged view of FIG. 16 (an enlarged view of a portion D surrounded by a broken line in FIG. 16). The wafer placement table 510 is configured similarly to the wafer placement table 310 except that the wafer placement table 510 includes the ceramic plate 520 in which the peripheral-region conductive film 529 is formed instead of the ceramic plate 320 in which the peripheral-region conductive film 329 is formed, and that the peripheral-region conductive film 529 and the plug conductive film 58 are connected by the connecting conductive film 458 and are formed with no gap therebetween. The connecting conductive film 458 may be omitted. In FIGS. 16 to 18, the same reference signs are assigned to the same configurations as those of the above-described embodiments. The ceramic plate 520 is configured similarly to the ceramic plate 320 except that the peripheral-region conductive film 529 is formed instead of the peripheral-region conductive film 329. The peripheral-region conductive film 529 is not formed on the FR support surface 26c, but is formed on the low-level surface 327c (the bottom surface of the recessed portion 327) where the plug arrangement hole 28 opens. A formation method, thickness, material, and the like of the peripheral-region conductive film 529 can be appropriately adopted from those described for the plug conductive film 58 and the peripheral-region conductive film 329. In the wafer placement table 510, due to the presence of the peripheral-region conductive film 529, a potential difference between the focus ring 60 and the low-level surface 327c, the surface recessed portion 57a, and the like can be reduced to some extent. Further, since the focus ring 60 does not contact the peripheral-region conductive film 529, generation of particles and dust due to contact between the focus ring 60 and the peripheral-region conductive film 529 can be suppressed. From a viewpoint of reducing the potential difference between the focus ring 60 and the low-level surface 327c, the surface recessed portion 57a, and the like, it is preferable that each film area S (e.g., the hatched area in FIG. 17) of the peripheral-region conductive films 529 is 25 mm² or more. The film area S is more preferably, for example, 50 mm² or more, and may be 100 mm² or more. The film area S may be, for example, 200 mm² or less. The peripheral-region conductive film 529 may be formed only on the low-level surface 327c, or may be formed from the low-level surface 327c to at least a part of a side surface of the recessed portion 327. The peripheral-region conductive film 529 is preferably formed over the entire circumference of the plug arrangement hole 28. It should be noted that, also for the peripheral-region conductive film 329 of the wafer placement table 310 and the wafer placement table 410 described above, each film area S is preferably 25 mm² or more, and the values described here can be appropriately adopted.

The wafer placement table 510 described above may include, for example, the electrostatic electrode 423. In that case, from a viewpoint of reducing the influence of the electric field of the electrostatic electrode 423, it is preferable that the peripheral-region conductive film 529 is provided with a gap of 0.25 mm or more, when viewed from above, on an inner side of the through hole 423a penetrating the electrostatic electrode 423. That is, it is preferable that a length e, which is a length in plan view between the peripheral-region conductive film 529 and the electrostatic electrode 423, is 0.25 mm or more. As the length e, the values described for the wafer placement table 410 can be appropriately adopted.

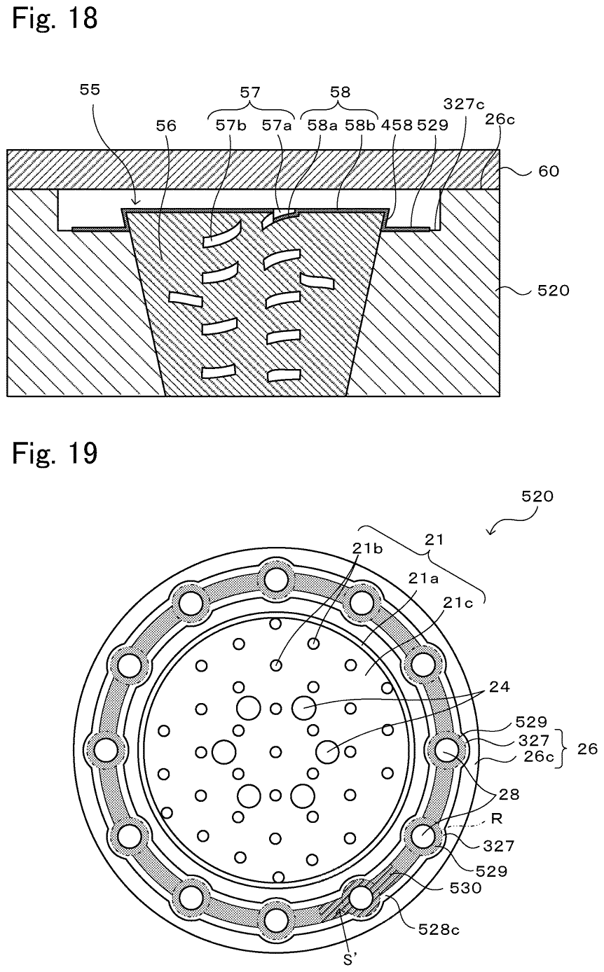

In the wafer placement table 510 described above, an auxiliary conductive film 530 formed continuously from the peripheral-region conductive film 529 (FIG. 19) may be provided on the surface of the ceramic plate 520. The auxiliary conductive film 530 is not formed on the FR support surface 26c, but is formed on the low-level surface 327c or a low-level surface 528c. The low-level surface 528c may be, for example, a bottom surface of a recessed portion formed similarly to the annular recessed portion 27. The auxiliary conductive film 530 may be formed so as to connect adjacent peripheral-region conductive films 529, or may be formed in an arc shape. A formation method, thickness, material, and the like of the auxiliary conductive film 530 can be appropriately adopted from those described for the plug conductive film 58 and the peripheral-region conductive film 329. By providing the auxiliary conductive film 530 in addition to the peripheral-region conductive film 529, an area of the conductive films can be increased, and a potential difference between the focus ring 60 and the low-level surface 327c, the surface recessed portion 57a, and the like can be reduced. Further, since the focus ring 60 does not contact the auxiliary conductive film 530, generation of particles and dust due to contact between the focus ring 60 and the auxiliary conductive film 530 also does not occur. From a viewpoint of reducing the potential difference between the focus ring 60 and the low-level surface 327c, the surface recessed portion 57a, and the like, it is preferable that a film area S′ (e.g., the hatched area in FIG. 19) of each peripheral-region conductive film 529 and a corresponding auxiliary conductive film 530 is 25 mm² or more. The film area S′ is more preferably, for example, 50 mm² or more, and may be 100 mm² or more. The film area S′ may be, for example, 200 mm² or less. When auxiliary conductive films 530 corresponding to respective peripheral-region conductive films 529 are connected to each other, the area of the connected auxiliary conductive film 530 may be equally divided to define the film area of each auxiliary conductive film 530 corresponding to each peripheral-region conductive film 529. The peripheral-region conductive films 529 and the auxiliary conductive film 530 may be formed only on the low-level surface 327c and the low-level surface 528c, or may be formed from the low-level surface 327c and the low-level surface 528c to at least a part of side surfaces of the recessed portion 327 and the like.

### EXAMPLES

Specific study examples of the member for semiconductor manufacturing apparatus of the present invention will be described below as examples. It should be noted that Experimental Examples 2 to 3 correspond to examples, and Experimental Example 1 corresponds to a comparative example. The present invention is not limited in any way to the following examples, and it goes without saying that the present invention can be implemented in various modes as long as they belong to the technical scope of the present invention.

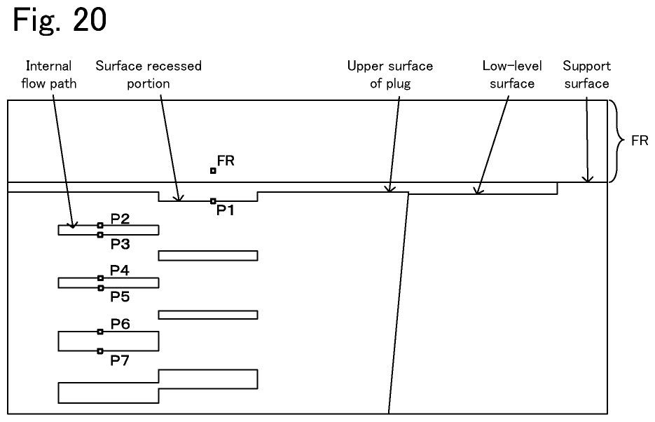

A simulation was performed to obtain a potential distribution when a voltage was applied such that a focus ring FR was at 2.7 kV and a base plate was at 0 V, for: (Experimental Example 1) a configuration in which neither a plug conductive film nor a peripheral-region conductive film was formed; (Experimental Example 2) a configuration in which a plug conductive film and a peripheral-region conductive film were formed with no gap therebetween; and (Experimental Example 3) a configuration in which a plug conductive film and a peripheral-region conductive film were formed with a gap of 1 μm therebetween. A diameter of an outer peripheral edge of the plug arrangement hole was set to 4 mm, and the peripheral region was a region having a length, when viewed from above, of 6 mm from the outer peripheral edge of the plug arrangement hole. Potentials at respective portions P1 to P7 shown in FIG. 20 were obtained, and a potential difference ΔV_{FR-P1} between the focus ring FR and a portion P1 (a bottom of the surface recessed portion), a potential difference ΔV_{P2-P3} between a portion P2 and a portion P3 (a ceiling and a bottom of an internal flow path appearing first from the top on the left side), a potential difference ΔV_{P4-P5} between a portion P4 and a portion P5 (a ceiling and a bottom of an internal flow path appearing second from the top on the left side), and a potential difference ΔV_{P6-P7} between a portion P6 and a portion P7 (a ceiling and a bottom of an internal flow path appearing third from the top on the left side) were calculated and summarized in Table 1. As shown in Table 1, in Experimental Example 1 having neither a plug conductive film nor a peripheral-region conductive film, the value of ΔV_{FR-P1} was very large, i.e., 587 V. In contrast, in Experimental Example 2 and Experimental Example 3 in which a plug conductive film and a peripheral-region conductive film were provided, the value of ΔV_{FR-P1} could be reduced to half or less of that of Experimental Example 1, and it was found that discharge in the surface recessed portion could be suppressed. Further, in Experimental Example 2 in which the plug conductive film and the peripheral-region conductive film were formed with no gap therebetween, the value of ΔV_{FR-P1} was 0, and it was found that discharge in the surface recessed portion could be further suppressed. On the other hand, in Experimental Example 3 in which the plug conductive film and the peripheral-region conductive film were formed with a gap therebetween, the potential differences ΔV_{P2-P3}, ΔV_{P4-P5}, and ΔV_{P6-P7} in the internal flow paths were generally small, and it was found that discharge in the internal flow paths could also be suppressed. It should be noted that, in all Experimental Examples, the value of the potential difference ΔV_{P6-P7} was larger than the values of ΔV_{P4-P5} and ΔV_{P2-P3}; this is because a distance between the ceiling and the bottom of the internal flow path appearing third from the top on the left side is long, and it is also possible to make this distance comparable to those of other internal flow paths so that ΔV_{P2-P3}, ΔV_{P4-P5}, and ΔV_{P6-P7} are all set to comparable values. A simulation in a case where only the plug conductive film was formed and no peripheral-region conductive film was formed was not performed; however, from the results of Experimental Examples 1 to 3, it was inferred that forming the plug conductive film tends to make the potential distribution in the surface recessed portion gentler, thereby suppressing discharge in the surface recessed portion.

TABLE 1

| | Experimental | Experimental | Experimental |
|---|---|---|---|
| | Example 1 | Example 2 | Example 3 |
| ΔV_{FR-P1} | 587 V | 0 V | 216 V |
| ΔV_{P2-P3} | 208 V | 184 V | 162 V |
| ΔV_{P4-P5} | 168 V | 184 V | 164 V |
| ΔV_{P6-P7} | 241 V | 283 V | 254 V |

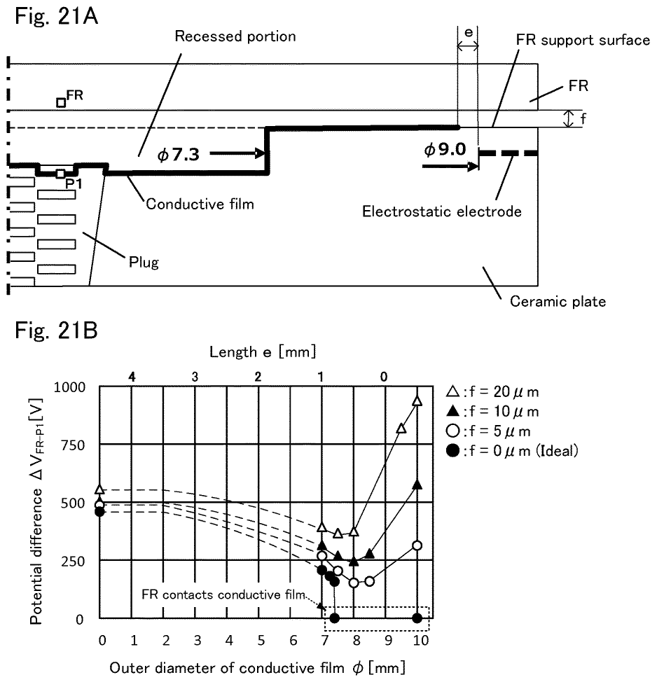

In Experimental Example 2 and Experimental Example 3 described above, examination was performed on the premise that the peripheral-region conductive film contacts the focus ring FR; however, a case is also conceivable where the peripheral-region conductive film does not contact the focus ring FR due to warpage of the focus ring or the like. In such a case, for example, the potential difference ΔV_{FR-P1} between the focus ring FR and the portion P1 (the bottom of the surface recessed portion) is considered to generally decrease as a distance between the focus ring FR and the conductive film is reduced and an area of the conductive film is increased. However, when an electrostatic electrode is embedded in the ceramic plate, it was observed that, as the area of the conductive film is increased, the potential difference ΔV_{FR-P1} decreases up to a certain point but then starts increasing from that point. Results of examination of this point are shown in FIGS. 21A and 21B. For the examination, simulation results of a potential distribution obtained when a voltage was applied such that the FR was −8.5 kV, a base was −5.3 kV, and the electrostatic electrode was −3 kV were used. The electrostatic electrode was assumed to be embedded at a depth such that a distance from the FR support surface was 350 μm. The depth of the recessed portion was set to 10 μm. FIGS. 21A and 21B are explanatory views in which a relationship between a length e (a length in plan view between the conductive film and the electrostatic electrode) and the potential difference ΔV_{FR-P1} is examined. FIG. 21A is an explanatory view of potential measurement locations, and FIG. 21B is a graph showing the relationship between the length e and the potential difference ΔV_{FR-P1}. As shown in FIG. 21B, when the conductive film contacts the focus ring FR, the potential difference ΔV_{FR-P1} became 0. On the other hand, when the conductive film does not contact the focus ring FR, the potential difference ΔV_{FR-P1} decreased as the conductive film became larger (as an outer diameter of the conductive film became larger) up to an outer diameter of the conductive film of about 8 mm (length e of 0.5 mm), but when it exceeded this, the potential difference ΔV_{FR-P1} increased. This was inferred to be caused by, for example, the conductive film receiving influence of an electric field by the electrostatic electrode. Although it depends on a distance (length f) between the FR support surface and the FR, from a viewpoint of reducing the potential difference ΔV_{FR-P1} by suppressing the influence of the electric field by the electrostatic electrode, it was inferred that the length e is preferably, for example, 0.25 mm or more, more preferably 0.3 mm or more, further preferably 0.5 mm or more. Further, from a viewpoint of reducing the potential difference ΔVFR−P1 by increasing the film area S of the conductive film, it was inferred that the length e is preferably, for example, 1 mm or less, more preferably 0.8 mm or less, further preferably 0.75 mm or less.

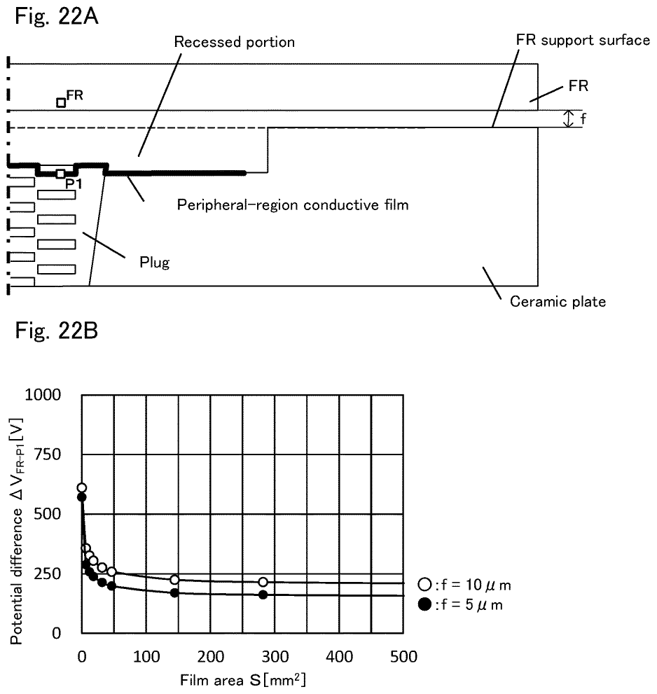

In Experimental Example 2 and Experimental Example 3 described above, the potential difference ΔV_{FR-P1} can be set to zero by bringing the peripheral-region conductive film into contact with the focus ring FR; however, it is also conceivable that the peripheral-region conductive film may be scraped due to sliding with the focus ring FR or the like, causing contamination by particles or dust, or causing secular change in attraction force. From a viewpoint of suppressing such contamination and secular change, examination was performed for a case where the conductive film is formed only in the recessed portion and is not formed on the FR support surface. In such a case, for example, the potential difference ΔV_{FR-P1} between the focus ring FR and the portion P1 (the bottom of the surface recessed portion) is considered to generally decrease as a distance between the focus ring FR and the conductive film is reduced and an area of the conductive film is increased. Results of examination of this point are shown in FIGS. 22A and 22B. For the examination, simulation results of a potential distribution obtained when a voltage was applied such that the FR was −8.5 kV and a base was −5.3 kV were used. The depth of the recessed portion was set to 10 μm. FIGS. 22A and 22B are explanatory views in which a relationship between a film area S (or a film area S′; the same applies hereinafter) of the conductive film and the potential difference ΔV_{FR-P1} is examined. FIG. 22A is an explanatory view of potential measurement locations, and FIG. 22B is a graph showing the relationship between the film area S and the potential difference ΔV_{FR-P1}. As shown in FIG. 22B, the larger the film area S, the smaller the potential difference ΔV_{FR-P1} became. Although it depends on a distance (length f) between the FR support surface and the FR, from a viewpoint of further reducing the potential difference ΔV_{FR-P1}, it was inferred that the film area S is preferably, for example, 25 mm² or more, more preferably 50 mm² or more, and may be 100 mm² or more. Since the potential difference ΔV_{FR-P1} became substantially constant when the film area S exceeded around 200 mm², it was inferred that the film area S may be, for example, 200 mm² or less.

What is claimed is:

1. A plug comprising:
an insulating and dense plug body;
a gas flow path that penetrates from a lower portion of the plug body and opens at an upper surface thereof, and a part of which is exposed on the surface as a recessed portion when viewed from above; and
a plug conductive film formed continuously along a wall surface of the recessed portion of the gas flow path and the upper surface of the plug body.

2. The plug according to claim 1,
wherein a length in the up-down direction from the upper surface of the plug body to a lower end of the recessed portion is 1% or more and 10% or less of a length of the plug body in the up-down direction.

3. The plug according to claim 1,
wherein the gas flow path is formed in a spiral shape.

4. The plug according to claim 1,
wherein the plug conductive film is a sputtered film.

5. A member for semiconductor manufacturing apparatus comprising:
a ceramic plate having, on its upper surface, a placement surface that is at least one of a wafer placement surface or a focus ring placement surface; and
the plug according to claim 1 disposed in a plug arrangement hole penetrating the ceramic plate in the up-down direction.

6. The member for semiconductor manufacturing apparatus according to claim 5,
wherein the plug is disposed in the plug arrangement hole that opens to the focus ring placement surface.

7. The member for semiconductor manufacturing apparatus according to claim 5, further comprising:
a conductive base member that is bonded to a lower surface of the ceramic plate and that is provided with a gas supply path communicating with the plug arrangement hole.

8. The member for semiconductor manufacturing apparatus according to claim 5, comprising:
a peripheral-region conductive film provided in a peripheral region around the plug arrangement hole in the placement surface, the peripheral-region conductive film being formed with a gap from the plug conductive film or with no gap therefrom,
wherein the plug arrangement hole opens in a low-level surface that is lower than a support surface that supports a wafer or a focus ring in the placement surface, and
the peripheral-region conductive film is formed from the support surface to the low-level surface.

9. The member for semiconductor manufacturing apparatus according to claim 8,
wherein the peripheral region is a region having a length, when viewed from above, of 7 mm or less from an outer peripheral edge of the plug arrangement hole.

10. The member for semiconductor manufacturing apparatus according to claim 8,
wherein a thickness of the peripheral-region conductive film is Rz or less, where Rz is a maximum height roughness of the support surface.

11. The member for semiconductor manufacturing apparatus according to claim 8, further comprising:
an electrostatic electrode embedded in the ceramic plate,
wherein the electrostatic electrode has a through hole for allowing the plug to pass therethrough, and
the peripheral-region conductive film is provided with a gap of 0.25 mm or more, when viewed from above, on an inner side of the through hole.

12. The member for semiconductor manufacturing apparatus according to claim 5, comprising:
a peripheral-region conductive film provided in a peripheral region around the plug arrangement hole in the placement surface, the peripheral-region conductive film being formed with a gap from the plug conductive film or with no gap therefrom,
wherein the plug arrangement hole opens in a low-level surface that is lower than a support surface that supports a wafer or a focus ring in the placement surface, and
the peripheral-region conductive film is not formed on the support surface but is formed on the low-level surface.

13. The member for semiconductor manufacturing apparatus according to claim 12,
wherein each film area of the peripheral-region conductive films is 50 mm² or more.

14. The member for semiconductor manufacturing apparatus according to claim 12, further comprising:
an auxiliary conductive film formed continuously from the peripheral-region conductive film,
wherein the auxiliary conductive film is not formed on the support surface but is formed on the low-level surface, and
a film area of each peripheral-region conductive film and a corresponding auxiliary conductive film is 50 mm² or more.
